(19) United States
(12) Patent Application Publication
(10) Pub. No.: US 2025/0081300 A1
(43) Pub. Date: Mar. 6, 2025

(54) DIELECTRIC HEATING DEVICE

(71) Applicant: Samsung Electronics Co., Ltd., Suwon-si (KR)

(72) Inventors: Jinsoo CHOI, Suwon-si (KR); Taedong GOH, Suwon-si (KR); Jihoon KIM, Suwon-si (KR); Minsik CHO, Suwon-si (KR); Bohwan CHOI, Suwon-si (KR); Youngho RYU, Suwon-si (KR)

(21) Appl. No.: 18/949,243

(22) Filed: Nov. 15, 2024

Related U.S. Application Data
(63) Continuation of application No. PCT/KR2023/004126, filed on Mar. 28, 2023.

(30) Foreign Application Priority Data
May 27, 2022 (KR) 10-2022-0065683
Aug. 30, 2022 (KR) 10-2022-0109367

(51) Int. Cl. H05B 6/48; H03K 17/687; H05B 6/54

(52) U.S. Cl. CPC H05B 6/48; H05B 6/54; H03K 17/687

(57) ABSTRACT

A dielectric heating device is provided. The dielectric heating device includes at least one power source, a load circuit including a plurality of electrodes and at least one inductor, and at least one driving circuit configured to output alternating-current power to the load circuit by using power provided from the at least one power source, wherein the plurality of electrodes include a plurality of top electrodes arranged in substantially the same plane, and one bottom electrode arranged in a plane parallel to the plane formed by the plurality of top electrodes.

### CROSS-REFERENCE TO RELATED APPLICATION(S)

This application is a continuation application, claiming priority under § 365 (c), of an International application No. PCT/KR2023/004126, filed on Mar. 28, 2023, which is based on and claims the benefit of a Korean patent application number 10-2022-0065683, filed on May 27, 2022, in the Korean Intellectual Property Office, and of a Korean patent application number 10-2022-0109367, filed on Aug. 30, 2022, in the Korean Intellectual Property Office, the disclosure of each of which is incorporated by reference herein in its entirety.

### BACKGROUND

### 1. Field

The disclosure relates to a dielectric heating device.

### 2 Description of Related Art

Dielectric heating is a technique of heating an object using a short-range electric field. When high-frequency power of several tens of MHz is applied to an object (e.g., an object to be heated), a high-frequency electric field is generated so that polar molecules in the object are rotated or vibrated, heating the object.

The dielectric heating technology is technically similar to that of the conventional microwave oven, but the dielectric heating device is driven at a frequency lower than the frequency used in the microwave oven, so that the penetration of heat is deepened and uniform heating is possible. It may be applied to food care (e.g., defrost, aging, drying, sterilization), clothing care (e.g., drying), skin care, brand-new drying methods, or carbon capture using the nature of uniform heating.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a dielectric heating device.

Additional aspects will be set forth in part in the description which follows and, in part, will be apparent from the description, or may be learned by practice of the presented embodiments.

In accordance with an aspect of the disclosure, a dielectric heating device is provided. The dielectric heating device includes at least one power source, a load circuit including a plurality of electrodes and at least one inductor, and at least one driving circuit configured to output alternating current (AC) power to the load circuit using power provided from the at least one power source, wherein the plurality of electrodes include a plurality of upper end electrodes positioned on substantially the same plane and one lower end electrode disposed on a plane parallel to the plane formed by the plurality of upper end electrodes.

In accordance with another aspect of the disclosure, a dielectric heating device is provided. The dielectric heating device includes at least one power source, a load circuit including a plurality of electrodes and at least one inductor, and at least one driving circuit configured to output AC power to the load circuit using power provided from the at least one power source, wherein the plurality of electrodes include a plurality of upper end electrodes disposed on a first plane and a plurality of lower end electrodes disposed on a second plane, and wherein the first plane is parallel to the second plane.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view for describing a power amplifier according to an embodiment of the disclosure;

FIG. 2 is a view for describing an operation of a dielectric heating device according to an embodiment of the disclosure;

FIG. 3 is a block diagram illustrating a dielectric heating device according to an embodiment of the disclosure;

FIG. 4 is a view for describing a load circuit of a dielectric heating device according to an embodiment of the disclosure;

FIG. 5 is a view for describing a structure of a plurality of electrodes of a dielectric heating device according to an embodiment of the disclosure;

FIG. 6 is a view for describing a load circuit of a dielectric heating device according to an embodiment of the disclosure;

FIG. 7 is a view for describing a structure of a plurality of electrodes of a dielectric heating device according to an embodiment of the disclosure;

FIG. 8 is a view for describing a load circuit of a dielectric heating device according to an embodiment of the disclosure;

FIG. 9 is a view for describing a structure of a plurality of electrodes of a dielectric heating device according to an embodiment of the disclosure;

FIG. 10 is a view for describing a structure of a plurality of electrodes of a dielectric heating device according to an embodiment of the disclosure;

FIG. 11 is a view for describing a load circuit of a dielectric heating device according to an embodiment of the disclosure;

FIG. 12 is a view for describing a structure of a plurality of electrodes of a dielectric heating device according to an embodiment of the disclosure;

FIG. 13 is a view for describing a structure of a plurality of electrodes of a dielectric heating device according to an embodiment of the disclosure;

FIG. 14 is a view for describing a structure of a plurality of electrodes of a dielectric heating device according to an embodiment of the disclosure;

FIG. 15 is a view for describing a structure of a plurality of electrodes of a dielectric heating device according to an embodiment of the disclosure;

FIG. 16 is a view for describing a structure of a plurality of electrodes of a dielectric heating device according to an embodiment of the disclosure;

FIG. 17 is a view for describing a structure of a plurality of electrodes of a dielectric heating device according to an embodiment of the disclosure;

FIG. 18 is a view for describing a structure of a plurality of electrodes of a dielectric heating device according to an embodiment of the disclosure; and

FIG. 19 is a view for describing a load circuit of a dielectric heating device according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

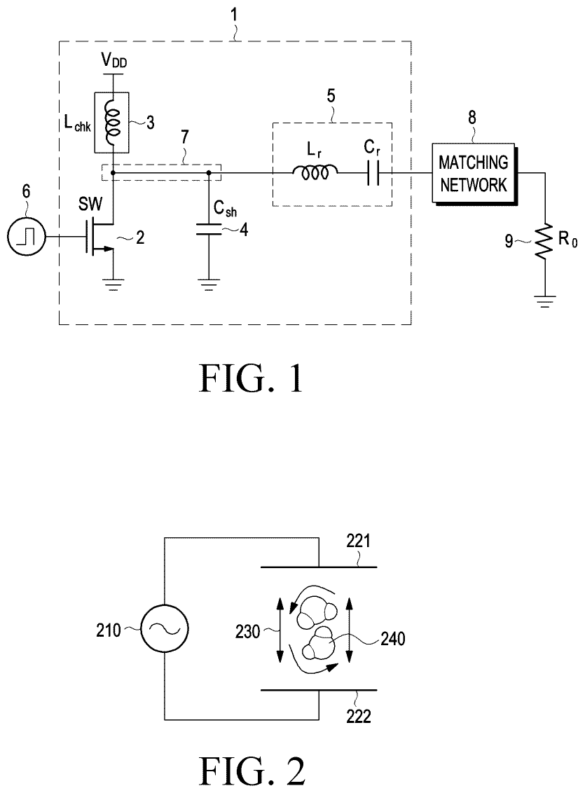

FIG. 1 is a view for describing a power amplifier according to an embodiment of the disclosure.

The power amplifier 1 may include a transistor 2, a radio frequency (RF) choke inductor Lchk 3, a shunt capacitor Csh 4, and a serial LC resonance circuit 5. The shunt capacitor 4 and the serial LC resonance circuit 5 may constitute a load network of the power amplifier 1.

The transistor 2 may operate by receiving a driving voltage VDD from an input power source, and may be turned on or off by receiving an input signal 6 (or a control signal) in a pulse form (e.g., a square wave) through an input terminal (e.g., a gate). For example, the transistor 2 may include a bipolar junction transistor (BJT) or a metal oxide semiconductor field effect transistor (MOSFET). Referring to FIG. 1, when the transistor 2 is an N-channel MOSFET (N-MOS), the input signal 6 may be a gate voltage applied to the gate terminal of the N-channel MOSFET. The source of the transistor 2 may be connected to a ground, and the drain thereof may be connected to an output node 7.

The RF choke inductor 3 may block the transfer of the RF signal from the input power source to the transistor 2 so that only the direct current (DC) current is transferred to the transistor 2.

The shunt capacitor 4 may be connected in parallel with the transistor 2 and may be discharged or charged while the transistor 2 is turned on or off. The shunt capacitor 4 may be a separate capacitor connected in parallel with the transistor 2, and may be described as including an internal capacitance (e.g., drain-source capacitance Cds) of the transistor 2.

RF power may be generated based on the transistor 2 being turned on or off according to the input signal 6, and the generated RF power may be transferred to the serial LC resonance circuit 5 through the output node 7. More specifically, when the transistor 2 is turned on (e.g., when the transistor 2 is saturated), the transistor 2 may be electrically shorted and thus be interpreted as a short circuit for the ground connected to the source, and the voltage of the output node 7 may be interpreted as zero. The current flowing to the transistor 2 through the RF choke inductor 3 may gradually increase. Thereafter, when the transistor 2 is turned off, the current flowing through the RF choke inductor 3 is directed to the shunt capacitor 4, and as the shunt capacitor 4 is gradually charged, the voltage of the output node 7 (e.g., the voltage across two opposite ends of the shunt capacitor 4) may increase until the maximum value is reached. Thereafter, as the shunt capacitor 4 is gradually discharged, a current flows from the shunt capacitor 4 to the serial LC resonance circuit 5 through the output node 7, and the voltage of the output node 7 (e.g., the voltage across two opposite ends of the shunt capacitor 4) may gradually decrease. In the power amplifier 1, for a high-efficiency operation (e.g., to minimize the power consumed by the transistor 2), the transistor 2, the shunt capacitor 4, and the input signal 6 may be configured so that, after the transistor 2 is turned off and before the transistor 2 is turned on again (e.g., before the current starts to flow again to the transistor 2 through the RF choke inductor 3), the voltage of the output node 7 (e.g., the voltage across two opposite ends of the shunt capacitor 4 and the drain-source voltage of the transistor 2) gradually decreases to 0 and the amount of change in which the voltage of the output node 7 decreases becomes 0. Thereafter, when the transistor 2 is turned on again, the current flowing through the RF choke inductor 3 may be directed to the transistor 2, and the voltage of the output node 7 may be maintained at zero while the transistor 2 is in the on state. As described above, as the drain-source voltage (e.g., the voltage of the output node 7) of the transistor 2 is 0 while the transistor 2 is in the on state and the current flowing through the RF choke inductor 3 is directed to the shunt capacitor 4 while the transistor 2 is in the off state, the current flowing to the transistor 2 through the RF choke inductor 3 is 0 (in other words, a period in which the drain-source voltage of the transistor 2 is non-zero and a period in which the drain-source current is non-zero do not overlap), and thus, the power consumed in the transistor 2 is ideally 0, enabling a high-efficiency operation of the transistor 2. However, in a non-ideal case, since the power amplifier 1 generates a signal (or RF power) based on the transistor 2 being turned on or off, the generated signal (or RF power) may include not only a desired frequency component (e.g., a fundamental component of the operating (resonant) frequency) but also a harmonic component of the second order or more, and power consumption may occur in the transistor 2 due to the harmonic component of the second order or more.

As described above, a current may flow from the RF choke inductor 3 to the transistor 2 or the shunt capacitor 4, or a current may flow from the shunt capacitor 4 to the serial LC resonance circuit 5 based on the transistor 2 being turned on or off according to the input signal 6 in the power amplifier 1, thereby generating an alternating current (AC) current. The generated AC current may be output to the outside (e.g., the matching network 8 and/or the load 9) through the serial LC resonance circuit 5, thereby generating an AC voltage in the load 9. The above-described generation of the AC current based on the above-described transistor 2 being turned on or off may be described as generation of a signal (or RF power) based on the transistor 2 being turned on or off.

The serial LC resonance circuit 5 may include an inductor Lr and a capacitor Cr connected in series with each other, and unlike illustrated, the serial LC resonance circuit 5 may include two or more inductors and two or more capacitors. The serial LC resonance circuit 5 may be configured to have a resonant frequency corresponding to (e.g., identical to) the operating frequency so as to resonate with the operating frequency of the input signal 6. For example, the serial LC resonance circuit 5 may be designed to include an inductor Lr and a capacitor Cr having an inductance value and a capacitance value so that the reactance value of the equivalent impedance of the serial LC resonance circuit 5 becomes 0 at the operating frequency of the input signal 6.

The matching network 8 may be connected to an output terminal of the power amplifier 1 (e.g., connected in series to the serial LC resonance circuit 5), and may provide impedance matching for matching the output impedance of the power amplifier 1 to the load 9.

The load 9 may include at least one hardware component (e.g., a circuit element) that receives, or operates by receiving, a signal (or RF power) generated by the power amplifier 1.

FIG. 2 is a view for describing an operation of a dielectric heating device according to an embodiment of the disclosure.

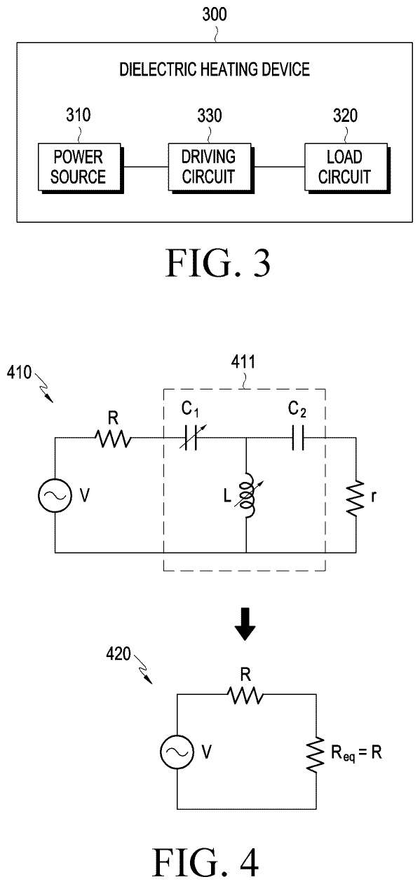

A dielectric heating device (e.g., the dielectric heating device 300 of FIG. 3) may include a high-frequency power source 210 and a plurality of electrodes (e.g., the first electrode 221 and the second electrode 222). A high-frequency electric field 230 may be provided between the first electrode 221 and the second electrode 222 by the high-frequency power source 210. The polar molecules 240 in the object positioned between the first electrode 221 and the second electrode 222 may be rotated and/or vibrated by the high-frequency electric field 230.

The dielectric heating device (e.g., the dielectric heating device 300 of FIG. 3) may provide a high-frequency electric field 230 between the first electrode 221 and the second electrode 222, thereby heating the object disposed between the first electrode 221 and the second electrode 222. The object may be heated by the motion of the polar molecules 240 in the object. The polar molecules 240 in the object may be positioned on the surface and inside of the object, and the portion where the object is heated may be determined according to the position where the polar molecules 240 are disposed in the object. The object may be uniformly heated due to the motion of the polar molecules 240 in the object.

The dielectric heating device (e.g., the dielectric heating device 300 of FIG. 3) may control freezing of the object disposed between the first electrode 221 and the second electrode 222 by providing the high-frequency electric field 230 between the first electrode 221 and the second electrode 222. For example, the dielectric heating device (e.g., the dielectric heating device 300 of FIG. 3) may provide a high-frequency electric field 230 between the first electrode 221 and the second electrode 222, thereby controlling supercooling of the object disposed between the first electrode 221 and the second electrode 222 or performing an operation of storing the object at a pre-freezing point.

An electronic device (e.g., the electronic device 300 of FIG. 3) may heat the object disposed between the first electrode 221 and the second electrode 222 by providing the high-frequency electric field 230 between the first electrode 221 and the second electrode 222. The object may be heated by the motion of the polar molecules 240 in the object. The polar molecules 240 in the object may be positioned on the surface and inside of the object, and the portion where the object is heated may be determined according to the position where the polar molecules 240 are disposed in the object. The object may be uniformly heated due to the motion of the polar molecules 240 in the object.

Hereinafter, the operation of heating the object will be mainly described, but it will be understood by one of ordinary skill in the art that the dielectric heating device (e.g., the dielectric heating device 300 of FIG. 3) may perform operations other than the operation of heating the object, the operation of supercooling the object, and the operation of storing the object at a pre-freezing point by providing the high-frequency electric field 230 between a plurality of electrodes (e.g., the first electrode 221 and the second electrode 222) of the dielectric heating device (e.g., the dielectric heating device 300 of FIG. 3).

FIG. 3 is a block diagram illustrating a dielectric heating device according to an embodiment of the disclosure.

Referring to FIG. 3, the dielectric heating device 300 according to an embodiment may include a power source 310, a load circuit 320, and a driving circuit 330. The driving circuit 330 may output power to the load circuit 320 using the power provided from the power source 310.

The power source 310 may provide power to the driving circuit 330. For example, the power source 310 may provide a driving voltage to a transistor included in the driving circuit 330. The dielectric heating device 300 may include one power source 310 or a plurality of power sources 310. For example, controlling the power source 310 by the dielectric heating device 300 may be understood as controlling at least one power source 310.

The driving circuit 330 may output AC power to the load circuit 320 using DC power provided from the power source 310. The dielectric heating device 300 may include one driving circuit 330 or a plurality of driving circuits 330. For example, controlling the driving circuit 330 by the dielectric heating device 300 may be understood as controlling the at least one driving circuit 330. According to an embodiment, the driving circuit 330 may include a transistor (e.g., the transistor 2 of FIG. 1) and/or a gate power source (e.g., the gate power source providing the input signal 6 of FIG. 2). According to an embodiment, the gate power source (e.g., the gate power source providing the input signal 6 of FIG. 2) may be described in concept as providing an input signal (e.g., a gate voltage) to the transistor (e.g., the transistor 2 of FIG. 1). According to an embodiment, an inductor (e.g., the choke inductor 3 of FIG. 1) and/or a capacitor (e.g., the shunt capacitor 4 of FIG. 1) may be included in the driving circuit 330. Alternatively, an inductor (e.g., the choke inductor 3 of FIG. 1) and/or a capacitor (e.g., the shunt capacitor 4 of FIG. 1) may be understood as elements separate from the driving circuit 330. According to an embodiment, the dielectric heating device 300 may not include an inductor (e.g., the choke inductor 3 of FIG. 1). The driving circuit 330 may be the power amplifier 1 of FIG. 1.

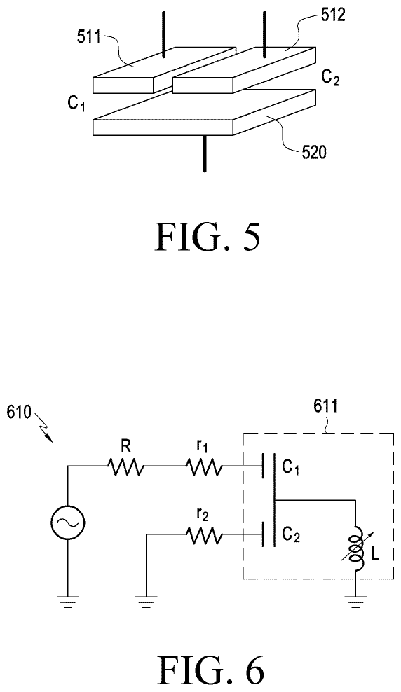

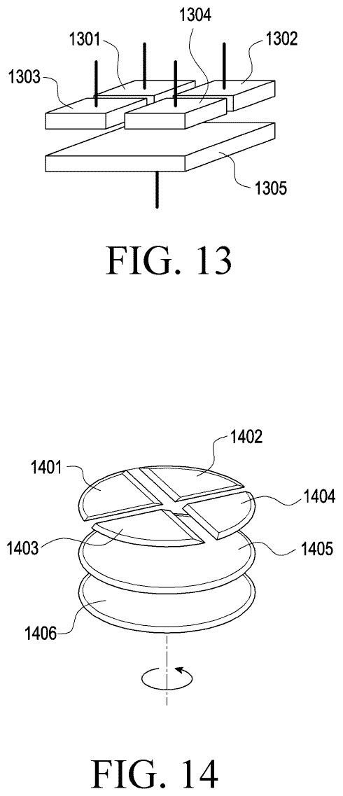

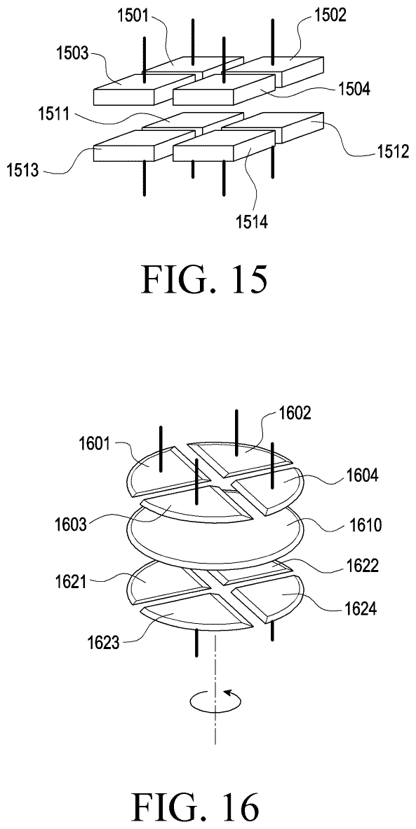

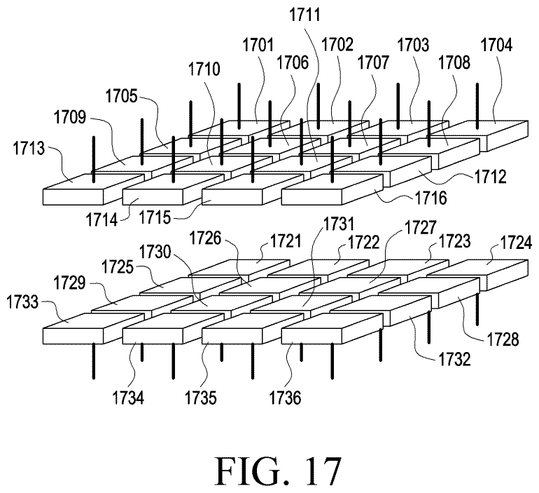

The load circuit 320 may include a plurality of electrodes (e.g., the first electrode 221 and the second electrode 222 of FIG. 2 or the electrodes of FIGS. 4 to 19 to be described below). By the AC power provided from the at least one driving circuit 330 to the load circuit 320, an electric field may be provided between the plurality of electrodes (e.g., the first electrode 221 and the second electrode 222 of FIG. 2 or the electrodes of FIGS. 4 to 19 to be described below). The supercooling of the target object disposed between the plurality of electrodes (e.g., the first electrode 221 and the second electrode 222 of FIG. 2 or the electrodes of FIGS. 4 to 19 to be described below) may be controlled by the electric field provided between the plurality of electrodes (e.g., the first electrode 221 and the second electrode 222 of FIG. 2 or the electrodes of FIGS. 4 to 19 to be described below). By the electric field provided between the plurality of electrodes (e.g., the first electrode 221 and the second electrode 222 of FIG. 2 or the electrodes of FIGS. 4 to 19 to be described below), the operation of storing the target object at a pre-freezing point disposed between the plurality of electrodes (e.g., the first electrode 221 and the second electrode 222 of FIG. 2 or the electrodes of FIGS. 4 to 19 to be described below) may be performed. The target object disposed between the plurality of electrodes (e.g., the first electrode 221 and the second electrode 222 of FIG. 2 or the electrodes of FIGS. 4 to 19 to be described below) may be heated by the electric field provided between the plurality of electrodes (e.g., the first electrode 221 and the second electrode 222 of FIG. 2 or the electrodes of FIGS. 4 to 19 to be described below). According to an embodiment, the load circuit 320 may include at least one capacitor. At least some of at least one capacitor included in the load circuit 320 may constitute at least some of a plurality of electrodes (e.g., the first electrode 221 and the second electrode 222 of FIG. 2 or the electrodes of FIGS. 4 to 19 to be described below). FIG. 2 illustrates an embodiment in which two electrodes are provided, but the number of electrodes is not limited. FIGS. 5, 6, 7, 8, and 9 illustrate an embodiment in which an object is disposed between three electrodes. FIGS. 10, 11, and 12 illustrate an embodiment in which an object is disposed between four electrodes. FIGS. 13 and 14 illustrate an embodiment in which an object is disposed between five electrodes. FIGS. 15, 16, and 18 illustrate an embodiment in which an object is disposed between five electrodes. FIG. 17 illustrates an embodiment in which an object is disposed between electrodes of a lattice structure (e.g., a lattice-shaped arrangement structure of m rows and n columns, where m and n are natural numbers).

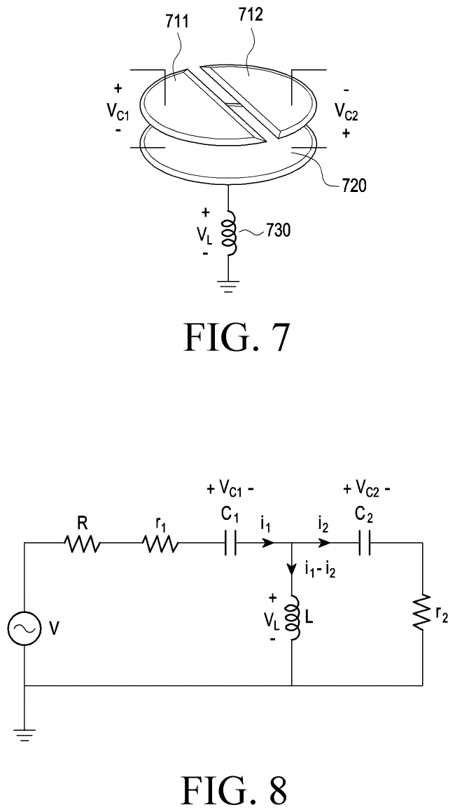

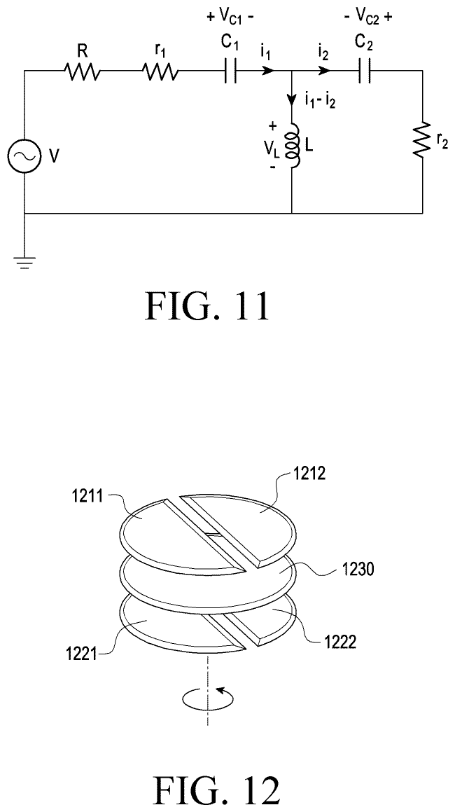

The load circuit 320 may include a matching circuit. For example, the load circuit 320 may include a matching circuit including at least one inductor (e.g., the at least one inductor L of FIG. 4, the at least one inductor 730 of FIG. 7, the at least one inductor 1030 of FIG. 10, the at least one inductor L of FIG. 11, or the at least one inductor L of FIG. 19). The load circuit 320 and the matching circuit may be configured as separate circuits, but for convenience of description, it is assumed that the load circuit 320 includes a matching circuit for impedance matching. At least one inductor (e.g., the at least one inductor L of FIG. 4, the at least one inductor 730 of FIG. 7, the at least one inductor 1030 of FIG. 10, the at least one inductor L of FIG. 11, or the at least one inductor L of FIG. 19) included in the load circuit 320 may include a variable inductor. As the inductance of the variable inductor included in the load circuit 320 is changed, impedance matching may be performed. For example, the inductance of the variable inductor included in the load circuit 320 may be changed by being deformed by the motor, but there is no limitation on how the inductance is changed. The load circuit 320 may include at least one capacitor (e.g., a variable capacitor). Impedance matching may be performed while the object is disposed between the plurality of electrodes (e.g., the first electrode 221 and the second electrode 222 of FIG. 2 or the electrodes of FIGS. 4 to 19 to be described below) of the load circuit 320.

FIG. 4 is a view for describing a load circuit of a dielectric heating device according to an embodiment of the disclosure.

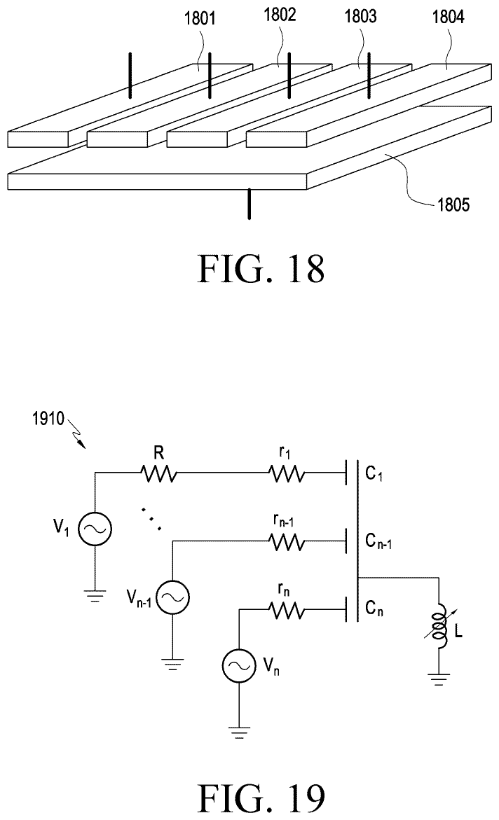

An equivalent circuit of the dielectric heating device 300 of FIG. 3 may be understood with reference to FIG. 4. FIG. 4 may be an equivalent circuit of the dielectric heating device 300 including one power source 310 and one driving circuit 330. An equivalent circuit for the dielectric heating device 300 including one or more power sources 310 and one or more driving circuits 330 is described with reference to FIGS. 18 and 19.

The load circuit 320 of FIG. 3 may be represented as the CLC structure 411 of the first circuit diagram 410 of FIG. 4. Referring to FIG. 4, the CLC structure 411 may be a structure in which a plurality of capacitors (e.g., the first capacitor C1 and the second capacitor C2) and at least one inductor (e.g., the at least one inductor L) are connected. The load circuit 320 of FIG. 3 may include a plurality of capacitors (e.g., the first capacitor C1 and the second capacitor C2 of FIG. 4) and at least one inductor (e.g., the at least one inductor L of FIG. 4). The plurality of capacitors (e.g., the first capacitor C1 and the second capacitor C2 of FIG. 4) and at least one inductor (e.g., the at least one inductor L of FIG. 4) included in the load circuit 320 of FIG. 3 may be represented as the CLC structure 411 of the first circuit diagram 410 of FIG. 4.

At least some of the plurality of capacitors (e.g., the first capacitor C1 and the second capacitor C2) included in the load circuit 320 of FIG. 3 may constitute at least some of the plurality of electrodes (e.g., the first electrode 221 and the second electrode 222 of FIG. 2 or the electrodes of FIGS. 4 to 19 to be described below). The plurality of capacitors (e.g., the first capacitor C1 and the second capacitor C2) and the plurality of electrodes (e.g., the first electrode 221 and the second electrode 222 of FIG. 2 or the electrodes of FIGS. 4 to 19 to be described below) are described below.

The object (e.g., the target object to be heated) disposed between the plurality of electrodes (e.g., the first electrode 221 and the second electrode 222 of FIG. 2 or the electrodes of FIGS. 4 to 19 to be described below) of the dielectric heating device 300 may be represented as a resistor r in the first circuit diagram 410 of FIG. 4.

The power supply unit including the power source 310 and the driving circuit 330 of FIG. 3 may be represented as a power source V and a characteristic impedance R in the first circuit diagram 410 of FIG. 4. In order to describe a case in which the dielectric heating device 300 includes one or more power sources 310 and one or more driving circuits 330, the power supply unit including the one or more power sources 310 and the one or more driving circuits 330 may be represented as one or more power sources V1, Vₙ₋₁, and Vₙ in the circuit diagram 1910 of FIG. 19 to be described below.

Referring to FIG. 4, the CLC structure 411 may be a structure in which the first capacitor C1, the at least one inductor L, and the second capacitor C2 are connected in a T-shape, but the connection structure is not limited thereto. At least one inductor L of the load circuit 320 may include a variable inductor. The dielectric heating device 300 may perform impedance matching using a variable inductor (e.g., at least one inductor L) included in the load circuit 320. For example, the dielectric heating device 300 may perform impedance matching by changing the inductance of the variable inductor (e.g., at least one inductor L). The inductance of the variable inductor (e.g., at least one inductor L) may be changed by changing the shape of the variable inductor (e.g., at least one inductor L) by the motor, but the method of changing the inductance of the variable inductor (e.g., at least one inductor L) is not limited. According to an embodiment, the first capacitor C1 of the load circuit 320 may be a variable capacitor or may not be a variable capacitor.

The second circuit diagram 420 of FIG. 4 may be an equivalent circuit according to an impedance matching operation of the load circuit 320. The power source V and the characteristic impedance R in the second circuit diagram 420 may be the power source V and the characteristic impedance R in the first circuit diagram 410. The load circuit 320 and the target object (e.g., the object disposed between the plurality of electrodes (e.g., the first electrode 221 and the second electrode 222 of FIG. 2 or the electrodes of FIGS. 4 to 19 to be described below) of the dielectric heating device 300) may be represented as an equivalent resistor R_{eq} in the second circuit diagram 420 of FIG. 4. In the second circuit diagram 420 of FIG. 4, the magnitude of the equivalent resistor R_{eq} may be substantially the same as the magnitude of the characteristic impedance R. In the second circuit diagram 420, changing the inductance of the variable inductor (e.g., at least one inductor L) so that the magnitude of the equivalent resistor R_{eq} is substantially the same as the magnitude of the characteristic impedance R may be referred to as impedance matching.

FIG. 5 is a view for describing a structure of a plurality of electrodes of a dielectric heating device according to an embodiment of the disclosure. FIG. 5 may be described with reference to FIGS. 3, 4, and 6. FIG. 6 is a view for describing a load circuit of a dielectric heating device according to an embodiment of the disclosure.

Referring to FIG. 5, according to an embodiment, the dielectric heating device 300 (e.g., the load circuit 320 of the dielectric heating device 300) may include a plurality of electrodes (e.g., the first upper end electrode 511, the second upper end electrode 512, and the lower end electrode 520). The plurality of upper end electrodes (e.g., the first upper end electrode 511 and the second upper end electrode 512) included in the load circuit 320 may be positioned on substantially the same plane. The lower end electrode 520 included in the load circuit 320 may be disposed on a plane parallel to the plane formed by the plurality of upper end electrodes (e.g., the first upper end electrode 511 and the second upper end electrode 512).

According to an embodiment, the first upper end electrode 511 and the lower end electrode 520 may form a first capacitor C1. A first area (e.g., an area corresponding to the first upper end electrode 511) of the first upper end electrode 511 and the lower end electrode 520 may form a first capacitor C1. The second upper end electrode 512 and the lower end electrode 520 may form a second capacitor C2. A second area (e.g., an area corresponding to the second upper end electrode 512) of the second upper end eyelash 512 and the lower end electrode 520 may form the second capacitor C2. Referring to FIGS. 5 and 6, the first capacitor C1 and the second capacitor C2 included in the load circuit 320 may share the lower end electrode 520.

According to an embodiment, the capacitance of the first capacitor C1 formed by the first upper end electrode 511 and the lower end electrode 520 may be substantially the same as the capacitance of the second capacitor C2 formed by the second upper end electrode 512 and the lower end electrode 520. For example, the area of the first upper end electrode 511 and the area of the second upper end electrode 512 may be substantially the same. For example, the size of the first area of the lower end electrode 520 corresponding to the first upper end electrode 511 and the size of the second area of the lower end electrode 520 corresponding to the second upper end electrode 512 may be substantially the same. According to an embodiment, the area of the first upper end electrode 511 and the area of the second upper end electrode 512 may be different.

FIG. 5 illustrates that the plurality of electrodes (e.g., the first upper end electrode 511, the second upper end electrode 512, and the lower end electrode 520) have the rectangular shape, but this is exemplary, and the shape of the plurality of electrodes (e.g., the first upper end electrode 511, the second upper end electrode 512, and the lower end electrode 520) is not limited thereto. For example, referring to FIG. 7, which is described below, the plurality of electrodes (e.g., the first upper end electrode 711, the second upper end electrode 712, and the lower end electrode 720) included in the load circuit 320 may have a round shape.

FIG. 5 illustrates that the plurality of upper end electrodes (e.g., the first upper end electrode 511 and the second upper end electrode 512) are composed of two electrodes, but the number of the plurality of upper end electrodes is not limited.

Referring to FIGS. 5 and 6, the load circuit 320 including the plurality of electrodes (e.g., the first upper end electrode 511, the second upper end electrode 512, and the lower end electrode 520) may be represented as the CLC structure 611 of FIG. 6. The CLC structure 611 of FIG. 6 may correspond to the CLC structure 411 of FIG. 4. The CLC structure 611 of FIG. 6 is one illustrated in the circuit diagram in which that the first capacitor C1 and the second capacitor C2 share the lower end electrode (e.g., the lower end electrode 520 of FIG. 5), and the first capacitor C1 and the second capacitor C2 of FIG. 6 may correspond to the first capacitor C1 and the second capacitor C2 of FIG. 5. The lower end electrode 520 included in the load circuit 320 may be electrically connected to at least one inductor L included in the load circuit 320. The CLC structure 611 of FIG. 6 represents that the lower end electrode (e.g., the lower end electrode 520 of FIG. 5) included in the load circuit 320 is electrically connected to at least one inductor L included in the load circuit 320. In the CLC structure 611 of FIG. 6, at least one inductor L included in the load circuit 320 may include a variable inductor.

The circuit diagram 610 of FIG. 6 may correspond to the first circuit diagram 410 of FIG. 4. A case in which the first capacitor C1 and the second capacitor C2 of the first circuit diagram 410 of FIG. 4 share the lower end electrode may be represented as the circuit diagram 610 of FIG. 6. In the circuit diagram 610 of FIG. 6, the first resistor r1 and the second resistor r2 may correspond to the resistor r of the first circuit diagram 410 of FIG. 4. The object (e.g., the target object to be heated) positioned between the plurality of electrodes (e.g., the first upper end electrode 511, the second upper end electrode 512, and the lower end electrode 520 of FIG. 5) included in the load circuit 320 may be represented as the first resistor r1 and the second resistor r2 of the circuit diagram 610 of FIG. 6.

FIG. 7 is a view for describing a structure of a plurality of electrodes of a dielectric heating device according to an embodiment of the disclosure. FIG. 7 may be described with reference to FIGS. 3, 4, and 8. FIG. 8 is a view for describing a load circuit of a dielectric heating device according to an embodiment of the disclosure.

Referring to FIG. 7, the dielectric heating device 300 (e.g., the load circuit 320 of the dielectric heating device 300) may include a plurality of electrodes (e.g., the first upper end electrode 711, the second upper end electrode 712, and the lower end electrode 720). Although FIGS. 7 and 5 illustrate that the shapes of the plurality of electrodes are different, this is merely to express that the shapes of the plurality of electrodes are not limited, and the plurality of electrodes (e.g., the first upper end electrode 711, the second upper end electrode 712, and the lower end electrode 720) of FIG. 7 may correspond to the plurality of electrodes (e.g., the first upper end electrode 511, the second upper end electrode 512, and the lower end electrode 520) of FIG. 5. The first upper end electrode 711 may correspond to the first upper end electrode 511 of FIG. 5. The second upper end electrode 712 may correspond to the second upper end electrode 512 of FIG. 5. The lower end electrode 720 may correspond to the lower end electrode 520 of FIG. 5. The lower end electrode 720 included in the load circuit 320 may be electrically connected to at least one inductor 730 included in the load circuit 320. At least one inductor 730 included in the load circuit 320 may include a variable inductor.

The circuit diagram of FIG. 8 may correspond to the circuit diagram 610 of FIG. 6. For example, the first capacitor formed by the first upper end electrode 711 and the lower end electrode 720 of FIG. 7 may be represented as the first capacitor C1 of FIG. 8. The second capacitor formed by the second upper end electrode 712 and the lower end electrode 720 of FIG. 7 may be represented as the second capacitor C2 of FIG. 8. At least one inductor 730 of FIG. 7 may be represented as at least one inductor L of FIG. 8. The first resistor r1 and the second resistor r2 of the circuit diagram of FIG. 8 may correspond to the first resistor r1 and the second resistor r2 of the circuit diagram 610 of FIG. 6.

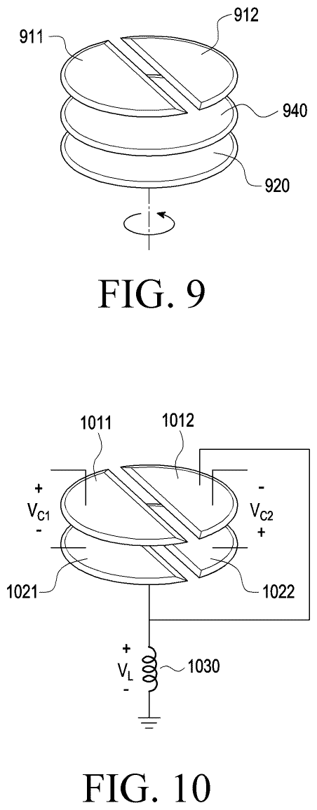

FIG. 9 is a view for describing a structure of a plurality of electrodes of a dielectric heating device according to an embodiment of the disclosure.

FIG. 9 is a view for describing a structure in which a plate (e.g., the plate 940 of FIG. 9) is disposed between a plurality of electrodes (e.g., the first upper end electrode 711, the second upper end electrode 712, and the lower end electrode 720) of FIG. 7.

The plurality of electrodes (e.g., the first upper end electrode 911, the second upper end electrode 912, and the lower end electrode 920) of FIG. 9 may be the plurality of electrodes (e.g., the first upper end electrode 711, the second upper end electrode 712, and the lower end electrode 720) of FIG. 7.

Referring to FIG. 9, the dielectric heating device 300 may include the plate 940 disposed between the plurality of electrodes (e.g., the first upper end electrode 911, the second upper end electrode 912, and the lower end electrode 920) included in the load circuit 320. For example, the plate 940 may be disposed between a first plane formed by the plurality of upper end electrodes (e.g., the first upper end electrode 911 and the second upper end electrode 912) and a second plane on which the lower end electrode 920 is disposed. An object (e.g., a target object to be heated) may be disposed on the plate 940. The material of the plate (e.g., the plate 940 of FIG. 9, the plate 1230 of FIG. 12, the plate 1405 of FIG. 14, and the plate 1610 of FIG. 16) is not limited.

According to an embodiment, the plate 940 may rotate. The dielectric heating device 300 may include a rotating device for rotating the plate 940. As the plate 940 rotates, the object (e.g., the target object to be heated) disposed on the plate 940 may be uniformly heated.

According to an embodiment, at least one electrode (e.g., the lower end electrode 920) among the plurality of electrodes (e.g., the first upper end electrode 911, the second upper end electrode 912, and the lower end electrode 920) included in the load circuit 320 may rotate. The dielectric heating device 300 may include a rotating device for rotating at least one electrode (e.g., the lower end electrode 920) among the plurality of electrodes (e.g., the first upper end electrode 911, the second upper end electrode 912, and the lower end electrode 920). For example, as the lower end electrode 920 included in the load circuit 320 rotates, the object (e.g., the target object to be heated) disposed between the plurality of electrodes (e.g., the first upper end electrode 911, the second upper end electrode 912, and the lower end electrode 920) may be uniformly heated. According to an embodiment, the plurality of upper end electrodes (e.g., the first upper end electrode 911 and the second upper end electrode 912) included in the load circuit 320 may rotate.

According to an embodiment, when the dielectric heating device 300 includes the plate 940, only the plate 940 may rotate, or only the lower end electrode 920 may rotate, or the plate 940 and the lower end electrode 920 each may rotate. According to an embodiment, when the dielectric heating device 300 does not include the plate 940, the lower end electrode 920 may rotate. In this case, the object (e.g., the target object) disposed on the lower end electrode 920 may also rotate.

The rotation scenario of the plate 940 and/or the lower end electrode 920 is not limited. For example, the dielectric heating device 300 may continuously rotate the plate 940 and/or the lower end electrode 920. The dielectric heating device 300 may stop the plate 940 and/or the lower end electrode 920 after rotating by a predetermined angle. The dielectric heating device 300 may repeat the operation of stopping the plate 940 and/or the lower end electrode 920 after rotating by a predetermined angle. The dielectric heating device 300 may rotate the plate 940 and/or the lower end electrode 920 at a constant speed. The dielectric heating device 300 may change the rotational speed of the plate 940 and/or the lower end electrode 920.

FIG. 10 is a view for describing a structure of a plurality of electrodes of a dielectric heating device according to an embodiment of the disclosure. FIG. 10 may be described with reference to FIGS. 3, 4, and 11. FIG. 11 is a view for describing a load circuit of a dielectric heating device according to an embodiment of the disclosure.

FIG. 10 is a view for describing an embodiment in which a plurality of lower end electrodes (e.g., the first lower end electrode 1021 and the second lower end electrode 1022) are included in the load circuit 320.

Referring to FIG. 10, the dielectric heating device 300 (e.g., the load circuit 320 of the dielectric heating device 300) may include a plurality of electrodes (e.g., the first upper end electrode 1011, the second upper end electrode 1012, the first lower end electrode 1021, and the second lower end electrode 1022). The plurality of electrodes included in the load circuit 320 may include a plurality of upper end electrodes (e.g., the first upper end electrode 1011 and the second upper end electrode 1012) and a plurality of lower end electrodes (e.g., the first lower end electrode 1021 and the second lower end electrode 1022). FIG. 10 illustrates that the load circuit 320 includes two upper end electrodes and two lower end electrodes, but this is exemplary, and the number of upper end electrodes and lower end electrodes included in the load circuit 320 is not limited.

According to an embodiment, the plurality of upper end electrodes (e.g., the first upper end electrode 1011 and the second upper end electrode 1012) included in the load circuit 320 may be disposed on the first plane. The plurality of lower end electrodes (e.g., the first lower end electrode 1021 and the second lower end electrode 1022) included in the load circuit 320 may be disposed on the second plane. The first plane on which the plurality of upper end electrodes (e.g., the first upper end electrode 1011 and the second upper end electrode 1012) are disposed and the second plane on which the plurality of lower end electrodes (e.g., the first lower end electrode 1021 and the second lower end electrode 1022) are disposed may be parallel to each other.

According to an embodiment, the first upper end electrode 1011 and the first lower end electrode 1021 may form a first capacitor C1. The second upper end electrode 1012 and the second lower end electrode 1022 may form a second capacitor C2.

According to an embodiment, the capacitance of the first capacitor C1 formed by the first upper end electrode 1011 and the first lower end electrode 1021 may be substantially the same as the capacitance of the second capacitor C2 formed by the second upper end electrode 1012 and the second lower end electrode 1022. For example, the area of the first upper end electrode 1011 and the area of the second upper end electrode 1012 may be substantially the same. The area of the first lower end electrode 1021 and the area of the second lower end electrode 1022 may be substantially the same. According to an embodiment, the area of the first upper end electrode 1011 and the area of the second upper end electrode 1012 may be different. The area of the first lower end electrode 1021 and the area of the second lower end electrode 1022 may be different.

Referring to FIG. 10, the dielectric heating device 300 (e.g., the load circuit 320 of the dielectric heating device 300) may include at least one inductor 1030. At least one inductor 1030 included in the load circuit 320 may include a variable inductor. According to an embodiment, the first lower end electrode 1021 may be electrically connected to at least one inductor 1030 included in the load circuit 320. The second upper end electrode 1012 may be electrically connected to at least one inductor 1030 included in the load circuit 320.

The first capacitor C1 of the circuit diagram of FIG. 11 may be the first capacitor C1 formed by the first upper end electrode 1011 and the first lower end electrode 1021 of FIG. 10. The second capacitor C2 of the circuit diagram of FIG. 11 may be the second capacitor C2 formed by the second upper end electrode 1012 and the second lower end electrode 1022 of FIG. 10. The at least one inductor L of the circuit diagram of FIG. 11 may be the at least one inductor 1030 of FIG. 10. The object (e.g., the target object to be heated) disposed between the plurality of electrodes (e.g., the first upper end electrode 1011, the second upper end electrode 1012, the first lower end electrode 1021, and the second lower end electrode 1022) of FIG. 10 may be represented as the first resistor r1 and the second resistor r2 of the circuit diagram of FIG. 11. The power source V and the characteristic impedance R of FIG. 11 may correspond to the power source V and the characteristic impedance R of FIG. 4.

FIG. 12 is a view for describing a structure of a plurality of electrodes of a dielectric heating device according to an embodiment of the disclosure.

FIG. 12 is a view for describing a structure in which a plate (e.g., the plate 1230 of FIG. 12) is disposed between a plurality of electrodes (e.g., the first upper end electrode 1011, the second upper end electrode 1012, the first lower end electrode 1021, and the second lower end electrode 1022) of FIG. 10.

The plurality of electrodes (e.g., the first upper end electrode 1211, the second upper end electrode 1212, the first lower end electrode 1221, and the second lower end electrode 1222) of FIG. 12 may be the plurality of electrodes (e.g., the first upper end electrode 1011, the second upper end electrode 1012, the first lower end electrode 1021, and the second lower end electrode 1022) of FIG. 10.

Referring to FIG. 12, the dielectric heating device 300 may include the plate 940 disposed between the plurality of electrodes (e.g., the first upper end electrode 1211, the second upper end electrode 1212, the first lower end electrode 1221, and the second lower end electrode 1222) included in the load circuit 320. For example, the plate 1230 may be disposed between a first plane formed by the plurality of upper end electrodes (e.g., the first upper end electrode 1211 and the second upper end electrode 1212) and a second plane on which the plurality of lower end electrodes (e.g., the first lower end electrode 1221 and the second lower end electrode 1222) are disposed. An object (e.g., a target object to be heated) may be disposed on the plate 1230.

According to an embodiment, the plate 1230 may rotate. The dielectric heating device 300 may include a rotating device for rotating the plate 1230. As the plate 1230 rotates, the object (e.g., the target object to be heated) disposed on the plate 1230 may be uniformly heated.

The rotation scenario of the plate 1230 is not limited. For example, the dielectric heating device 300 may continuously rotate the plate 1230. The dielectric heating device 300 may stop the plate 1230 after rotating by a predetermined angle. The dielectric heating device 300 may repeat the operation of stopping the plate 1230 after rotating the plate 1230 by the predetermined angle. The dielectric heating device 300 may rotate the plate 1230 at a constant speed. The dielectric heating device 300 may change the rotational speed of the plate 1230.

FIG. 13 is a view for describing a structure of a plurality of electrodes of a dielectric heating device according to an embodiment of the disclosure. FIG. 13 may be described with reference to FIGS. 3, 4, and 6.

Referring to FIG. 13, a lattice-shaped upper end electrode structure may be understood.

Referring to FIG. 13, according to an embodiment, the dielectric heating device 300 (e.g., the load circuit 320 of the dielectric heating device 300) may include a plurality of upper end electrodes (e.g., the first upper end electrode 1301, the second upper end electrode 1302, the third upper end electrode 1303, and the fourth upper end electrode 1304), and one lower end electrode 1305. The plurality of upper end electrodes (e.g., the first upper end electrode 1301, the second upper end electrode 1302, the third upper end electrode 1303, and the fourth upper end electrode 1304) included in the load circuit 320 may be positioned on substantially the same plane. The lower end electrode 1305 included in the load circuit 320 may be disposed on a plane parallel to the plane formed by the plurality of upper end electrodes (e.g., the first upper end electrode 1301, the second upper end electrode 1302, the third upper end electrode 1303, and the fourth upper end electrode 1304).

According to an embodiment, electrodes that are not adjacent to each other among the plurality of upper end electrodes (e.g., the first upper end electrode 1301, the second upper end electrode 1302, the third upper end electrode 1303, and the fourth upper end electrode 1304) may be connected to one node. The first upper end electrode 1301 and the fourth upper end electrode 1304 may be connected to one node. The second upper end electrode 1302 and the third upper end electrode 1303 may be connected to one node. The first upper end electrode 1301, the fourth upper end electrode 1304, and the lower end electrode 1305 may form a first capacitor (C1 of FIG. 6). A first area (e.g., the area corresponding to the first upper end electrode 1301) of the first upper end electrode 1301, the fourth upper end electrode 1304, or the lower end electrode 1305, and a fourth area (e.g., the area corresponding to the fourth upper end electrode 1304) of the lower end electrode 1305 may form the first capacitor C1. The second upper end electrode 1302, the third upper end electrode 1303, and the lower end electrode 1305 may form a second capacitor (C2 of FIG. 6). A second area (e.g., the area corresponding to the second upper end electrode 1302) of the second upper end electrode 1302, the third upper end electrode 1303, or the lower end electrode 1305, and a third area (e.g., the area corresponding to the third upper end electrode 1303) of the lower end electrode 1305 may form the second capacitor C2. Referring to FIGS. 13 and 6, the first capacitor C1 and the second capacitor C2 included in the load circuit 320 may share the lower end electrode 1305.

According to an embodiment, the capacitance of the first capacitor (e.g., C1 of FIG. 6) formed by the first upper end electrode 1301, the fourth upper end electrode 1304, and the lower end electrode 1305 may be substantially the same as the capacitance of the second capacitor (e.g., C2 of FIG. 6) formed by the second upper end electrode 1302, the third upper end electrode 1303, and the lower end electrode 1305. For example, the area of the first upper end electrode 1301, the area of the second upper end electrode 1302, the area of the third upper end electrode 1303, and the area of the fourth upper end electrode 1304 may be substantially the same. For example, the size of the first area of the lower end electrode 1305 corresponding to the first upper end electrode 1301, the size of the second area of the lower end electrode 1305 corresponding to the second upper end electrode 1302, the size of the third area of the lower end electrode 1305 corresponding to the third upper end electrode 1303, and the size of the fourth area of the lower end electrode 1305 corresponding to the fourth upper end electrode 1304 may be substantially the same. According to an embodiment, at least one of the area of the first upper end electrode 1301, the area of the second upper end electrode 1302, the area of the third upper end electrode 1303, or the area of the fourth upper end electrode 1304 may have a different area.

FIG. 13 illustrates that the plurality of electrodes (e.g., the first upper end electrode 1301, the second upper end electrode 1302, the third upper end electrode 1303, the fourth upper end electrode 1304, and the lower end electrode 1305) have a rectangular shape, but this is exemplary, and the shapes of the plurality of electrodes (e.g., the first upper end electrode 1301, the second upper end electrode 1302, the third upper end electrode 1303, the fourth upper end electrode 1304, and the lower end electrode 1305) are not limited thereto. For example, referring to FIG. 14, which is described below, the plurality of electrodes (e.g., the first upper end electrode 1401, the second upper end electrode 1402, the third upper end electrode 1403, the fourth upper end electrode 1404, and the lower end electrode 1406) included in the load circuit 320 may have a round shape.

Referring to FIG. 13, the load circuit 320 including a plurality of electrodes (e.g., the first upper end electrode 1301, the second upper end electrode 1302, the third upper end electrode 1303, the fourth upper end electrode 1304, and the lower end electrode 1305) may be represented as the CLC structure 611 of FIG. 6. The CLC structure 611 of FIG. 6 may correspond to the CLC structure 411 of FIG. 4. The CLC structure 611 of FIG. 6 may be one represented in the circuit diagram in which the first capacitor C1 and the second capacitor C2 share the lower end electrode (e.g., the lower end electrode 1305 of FIG. 13). The lower end electrode 1305 included in the load circuit 320 may be electrically connected to at least one inductor (e.g., L of FIG. 6) included in the load circuit 320. The CLC structure 611 of FIG. 6 represents that the lower end electrode (e.g., the lower end electrode 1305 of FIG. 5) included in the load circuit 320 is electrically connected to at least one inductor L included in the load circuit 320. In the CLC structure 611 of FIG. 6, at least one inductor L included in the load circuit 320 may include a variable inductor.

Referring to FIG. 13, the dielectric heating device 300 may activate only some of the plurality of upper end electrodes (e.g., the first upper end electrode 1301, the second upper end electrode 1302, the third upper end electrode 1303, and the fourth upper end electrode 1304). The dielectric heating device 300 may activate only some of the plurality of upper end electrodes (e.g., the first upper end electrode 1301, the second upper end electrode 1302, the third upper end electrode 1303, the fourth upper end electrode 1304, and the fourth upper end electrode 1304) based on the type, shape, and/or position of the object (e.g., the target object) disposed between the plurality of electrodes (e.g., the first upper end electrode 1301, the second upper end electrode 1302, the third upper end electrode 1303, and the fourth upper end electrode 1305). For example, the dielectric heating device 300 may activate only some electrodes corresponding to the position of the target object among the plurality of upper end electrodes (e.g., the first upper end electrode 1301, the second upper end electrode 1302, the third upper end electrode 1303, and the fourth upper end electrode 1304). For example, the dielectric heating device may include a plurality of switches respectively corresponding to the plurality of upper end electrodes (e.g., the first upper end electrode 1301, the second upper end electrode 1302, the third upper end electrode 1303, and the fourth upper end electrode 1304). By controlling the plurality of switches, the dielectric heating device 300 may activate only some electrodes corresponding to the position of the target object among the plurality of upper end electrodes (e.g., the first upper end electrode 1301, the second upper end electrode 1302, the third upper end electrode 1303, and the fourth upper end electrode 1304). It is exemplary that the dielectric heating device 300 includes switches and activates some electrodes by controlling the switches, and the method in which the dielectric heating device 300 controls whether to activate some electrodes is not limited.

FIG. 14 is a view for describing a structure of a plurality of electrodes of a dielectric heating device according to an embodiment of the disclosure. FIG. 14 may be described with reference to FIGS. 3, 4, and 13.

Referring to FIG. 14, the dielectric heating device 300 (e.g., the load circuit 320 of the dielectric heating device 300) may include a plurality of electrodes (e.g., the first upper end electrode 1401, the second upper end electrode 1402, the third upper end electrode 1403, the fourth upper end electrode 1404, and the lower end electrode 1406). Although FIGS. 14 and 13 illustrate that the shapes of the plurality of electrodes are different, this is merely to express that the shapes of the plurality of electrodes are not limited, and the plurality of electrodes (e.g., the first upper end electrode 1401, the second upper end electrode 1402, the third upper end electrode 1403, the fourth upper end electrode 1404, and the lower end electrode 1406) of FIG. 14 may correspond to the plurality of electrodes (e.g., the first upper end electrode 1301, the second upper end electrode 1302, the third upper end electrode 1303, the fourth upper end electrode 1304, and the lower end electrode 1305) of FIG. 13. The first upper end electrode 1401 may correspond to the first upper end electrode 1301 of FIG. 13. The second upper end electrode 1402 may correspond to the second upper end electrode 1302 of FIG. 13. The third upper end electrode 1403 may correspond to the third upper end electrode 1303 of FIG. 13. The fourth upper end electrode 1404 may correspond to the fourth upper end electrode 1304 of FIG. 13. The lower end electrode 1406 may correspond to the lower end electrode 1305 of FIG. 13. The lower end electrode 1406 included in the load circuit 320 may be electrically connected to at least one inductor (e.g., L of FIG. 6) included in the load circuit 320. At least one inductor (e.g., L of FIG. 6) included in the load circuit 320 may include a variable inductor.

Referring to FIG. 14, the dielectric heating device 300 may include a plate 1405 disposed between the plurality of electrodes (e.g., the first upper end electrode 1401, the second upper end electrode 1402, the third upper end electrode 1403, the fourth upper end electrode 1404, and the lower end electrode 1406). For example, the plate 1405 may be disposed between a first plane formed by the plurality of upper end electrodes (e.g., the first upper end electrode 1401, the second upper end electrode 1402, the third upper end electrode 1403, and the fourth upper end electrode 1404) and a second plane on which the lower end electrode 1406 is disposed. An object (e.g., a target object to be heated) may be disposed on the plate 1405.

According to an embodiment, the plate 1405 may rotate. The dielectric heating device 300 may include a rotating device for rotating the plate 1405. As the plate 1405 rotates, the object (e.g., the target object to be heated) disposed on the plate 1405 may be uniformly heated.

According to an embodiment, the dielectric heating device 300 may not include the plate 1405 between the plurality of electrodes (e.g., the first upper end electrode 1401, the second upper end electrode 1402, the third upper end electrode 1403, the fourth upper end electrode 1404, and the lower end electrode 1406).

According to an embodiment, at least one electrode (e.g., the lower end electrode 1406) among the plurality of electrodes (e.g., the first upper end electrode 1401, the second upper end electrode 1402, the third upper end electrode 1403, the fourth upper end electrode 1404, and the lower end electrode 1406) included in the load circuit 320 may rotate. The dielectric heating device 300 may include a rotating device for rotating at least one electrode (e.g., the lower end electrode 1406) among a plurality of electrodes (e.g., the first upper end electrode 1401, the second upper end electrode 1402, the third upper end electrode 1403, the fourth upper end electrode 1404, and the lower end electrode 1406). For example, as the lower end electrode 1406 included in the load circuit 320 rotates, the object (e.g., the target object to be heated) disposed between a plurality of electrodes (e.g., the first upper end electrode 1401, the second upper end electrode 1402, the third upper end electrode 1403, the fourth upper end electrode 1404, and the lower end electrode 1406) may be uniformly heated. According to an embodiment, the plurality of upper end electrodes (e.g., the first upper end electrode 1401, the second upper end electrode 1402, the third upper end electrode 1403, and the fourth upper end electrode 1404) included in the load circuit 320 may rotate.

According to an embodiment, when the dielectric heating device 300 includes the plate 1405, only the plate 1405 may rotate, or only the lower end electrode 1406 may rotate, or the plate 1405 and the lower end electrode 1406 each may rotate. According to an embodiment, when the dielectric heating device 300 does not include the plate 1405, the lower end electrode 1406 may rotate. In this case, the object (e.g., the target object) disposed on the lower end electrode 1406 may also rotate.

The rotation scenario of the plate 1405 and/or the lower end electrode 1406 is not limited. The rotation scenario of the plate 1405 and/or the lower end electrode 1406 may be understood similarly to the rotation scenario of the plate 940 and/or the lower end electrode 920 of FIG. 9.

FIG. 15 is a view for describing a structure of a plurality of electrodes of a dielectric heating device according to an embodiment of the disclosure. FIG. 15 may be described with reference to FIGS. 3, 4, and 11.

Referring to FIG. 15, an upper end electrode structure in a lattice shape and a lower end electrode structure in a lattice shape may be understood.

Referring to FIG. 15, the dielectric heating device 300 (e.g., the load circuit 320 of the dielectric heating device 300) may include a plurality of electrodes (e.g., the first upper end electrode 1501, the second upper end electrode 1502, the third upper end electrode 1503, the fourth upper end electrode 1504, the first lower end electrode 1511, the second lower end electrode 1512, the third lower end electrode 1513, and the fourth lower end electrode 1514). The plurality of electrodes included in the load circuit 320 may include a plurality of upper end electrodes (e.g., the first upper end electrode 1501, the second upper end electrode 1502, the third upper end electrode 1503, and the fourth upper end electrode 1504) and a plurality of lower end electrodes (e.g., the first lower end electrode 1511, the second lower end electrode 1512, the third lower end electrode 1513, and the fourth lower end electrode 1514).

According to an embodiment, the plurality of upper end electrodes (e.g., the first upper end electrode 1501, the second upper end electrode 1502, the third upper end electrode 1503, and the fourth upper end electrode 1504) included in the load circuit 320 may be disposed on the first plane. The plurality of lower end electrodes (e.g., the first lower end electrode 1511, the second lower end electrode 1512, the third lower end electrode 1513, and the fourth lower end electrode 1514) included in the load circuit 320 may be disposed on the second plane. The first plane on which the plurality of upper end electrodes (e.g., the first upper end electrode 1501, the second upper end electrode 1502, the third upper end electrode 1503, and the fourth upper end electrode 1504) are disposed and the second plane on which the plurality of lower end electrodes (e.g., the first lower end electrode 1511, the second lower end electrode 1512, the third lower end electrode 1513, and the fourth lower end electrode 1514) are disposed may be parallel.

According to an embodiment, the first upper end electrode 1501, the fourth upper end electrode 1504, the first lower end electrode 1511, and the fourth lower end electrode 1514 may form a first capacitor (e.g., C1 of FIG. 11). The second upper end electrode 1502, the third upper end electrode 1503, the second lower end electrode 1512, and the third lower end electrode 1513 may form a second capacitor (e.g., C2 of FIG. 11).

According to an embodiment, the capacitance of the first capacitor (e.g., C1 of FIG. 11) formed by the first upper end electrode 1501, the fourth upper end electrode 1504, the first lower end electrode 1511, and the fourth lower end electrode 1514 may be substantially the same as the capacitance of the second capacitor (e.g., C2 of FIG. 11) formed by the second upper end electrode 1502, the third upper end electrode 1503, the second lower end electrode 1512, and the third lower end electrode 1513. For example, the area of the first upper end electrode 1501, the area of the second upper end electrode 1502, the area of the third upper end electrode 1503, and the area of the fourth upper end electrode 1504 may be substantially the same. The area of the first lower end electrode 1511, the area of the second lower end electrode 1512, the area of the third lower end electrode 1513, and the area of the fourth lower end electrode 1514 may be substantially the same. According to an embodiment, at least one of the area of the first upper end electrode 1501, the area of the second upper end electrode 1502, the area of the third upper end electrode 1503, or the area of the fourth upper end electrode 1504 may have a different area.

The dielectric heating device 300 (e.g., the load circuit 320 of the dielectric heating device 300) may include at least one inductor (e.g., L of FIG. 11). At least one inductor (e.g., L of FIG. 11) included in the load circuit 320 may include a variable inductor. The first lower end electrode 1511 may be electrically connected to at least one inductor (e.g., L of FIG. 11) included in the load circuit 320. The fourth lower end electrode 1514 may be electrically connected to at least one inductor (e.g., L of FIG. 11) included in the load circuit 320. The second upper end electrode 1502 may be electrically connected to at least one inductor (e.g., L of FIG. 11) included in the load circuit 320. The third upper end electrode 1503 may be electrically connected to at least one inductor (e.g., L of FIG. 11) included in the load circuit 320.

The first capacitor C1 of the circuit diagram of FIG. 11 may be the first capacitor C1 formed by the first upper end electrode 1501, the fourth upper end electrode 1504, the first lower end electrode 1511, and the fourth lower end electrode 1514 of FIG. 15. The second capacitor C2 of the circuit diagram of FIG. 11 may be the second capacitor C2 formed by the second upper end electrode 1502, the third upper end electrode 1503, the second lower end electrode 1512, and the third lower end electrode 1513 of FIG. 15. The object (e.g., the target object to be heated) disposed between the plurality of electrodes (e.g., the first upper end electrode 1501, the second upper end electrode 1502, the third upper end electrode 1503, the fourth upper end electrode 1504, the first lower end electrode 1511, the second lower end electrode 1512, the third lower end electrode 1513, and the fourth lower end electrode 1514) of FIG. 15 may be represented as the first resistor r1 and the second resistor r2 of the circuit diagram of FIG. 11. The power source V and the characteristic impedance R of FIG. 11 may correspond to the power source V and the characteristic impedance R of FIG. 4.

FIG. 16 is a view for describing a structure of a plurality of electrodes of a dielectric heating device according to an embodiment of the disclosure.

FIG. 16 is a view for describing a structure in which a plate (e.g., the plate 1610 of FIG. 16) is disposed between the plurality of electrodes (e.g., the first upper end electrode 1501, the second upper end electrode 1502, the third upper end electrode 1503, the fourth upper end electrode 1504, the first lower end electrode 1511, the second lower end electrode 1512, the third lower end electrode 1513, and the fourth lower end electrode 1514) of FIG. 15.

The plurality of electrodes of FIG. 16 (e.g., the first upper end electrode 1601, the second upper end electrode 1602, the third upper end electrode 1603, the fourth upper end electrode 1604, the first lower end electrode 1611, the second lower end electrode 1612, the third lower end electrode 1613, and the fourth lower end electrode 1614) may be the plurality of electrodes of FIG. 15 (e.g., the first upper end electrode 1501, the second upper end electrode 1502, the third upper end electrode 1503, the fourth upper end electrode 1504, the first lower end electrode 1511, the second lower end electrode 1512, the third lower end electrode 1513, and the fourth lower end electrode 1514).

Referring to FIG. 16, the dielectric heating device 300 may include the plate 1610 disposed between the plurality of electrodes (e.g., the first upper end electrode 1601, the second upper end electrode 1602, the third upper end electrode 1603, the fourth upper end electrode 1604, the first lower end electrode 1611, the second lower end electrode 1612, the third lower end electrode 1613, and the fourth lower end electrode 1614) included in the load circuit 320. For example, the plate 1610 may be disposed between a first plane formed by the plurality of upper end electrodes (e.g., the first upper end electrode 1601, the second upper end electrode 1602, the third upper end electrode 1603, and the fourth upper end electrode 1604) and a second plane on which the plurality of lower end electrodes (e.g., the first lower end electrode 1611, the second lower end electrode 1612, the third lower end electrode 1613, and the fourth lower end electrode 1614) are disposed. An object (e.g., a target object to be heated) may be disposed on the plate 1610.

According to an embodiment, the plate 1610 may rotate. The dielectric heating device 300 may include a rotating device for rotating the plate 1610. As the plate 1610 rotates, the object (e.g., the target object to be heated) disposed on the plate 1610 may be uniformly heated.

The rotation scenario of the plate 1610 is not limited. The rotation scenario of the plate 1610 may be understood similarly to the rotation scenario of the plate 1230 of FIG. 12.

FIG. 17 is a view for describing a structure of a plurality of electrodes of a dielectric heating device according to an embodiment of the disclosure. FIG. 17 may be described with reference to FIGS. 3, 4, 13, and 15.

FIG. 17 is a view for describing that the number of the plurality of electrodes included in the dielectric heating device 300 (e.g., the load circuit 320 of the dielectric heating device 300) is not limited. The upper end electrodes of the dielectric heating device 300 (e.g., the load circuit 320 of the dielectric heating device 300) may be disposed in a lattice structure (e.g., a lattice-shaped arrangement structure of m rows and n columns, where m and n are natural numbers). The lower end electrodes of the dielectric heating device 300 (e.g., the load circuit 320 of the dielectric heating device 300) may be disposed in a lattice structure (e.g., a lattice-shaped arrangement structure of m rows and n columns, where m and n are natural numbers). Referring to FIG. 17, the areas of the plurality of electrodes (e.g., the upper end electrodes 1701 to 1716 and/or the lower end electrodes 1721 to 1736) included in the dielectric heating device 300 may be the same. Alternatively, the areas of at least some of the plurality of electrodes (e.g., the upper end electrodes 1701 to 1716 and/or the lower end electrodes 1721 to 1736) included in the dielectric heating device 300 may be different from each other. The area of each of the plurality of electrodes (e.g., the upper end electrodes 1701 to 1716 and/or the lower end electrodes 1721 to 1736) included in the dielectric heating device 300 is not limited.

For example, referring to FIGS. 17 and 13, the dielectric heating device 300 (e.g., the load circuit 320 of the dielectric heating device 300) may include a plurality of upper end electrodes (e.g., 16 upper end electrodes 1701 to 1716) and one lower end electrode (e.g., the lower end electrode 1305 of FIG. 13). The plurality of upper end electrodes (e.g., the 16 upper end electrodes 1701 to 1716) and one lower end electrode (e.g., the lower end electrode 1305 of FIG. 13) may be understood similarly to the plurality of upper end electrodes (e.g., the first upper end electrode 1301, the second upper end electrode 1302, the third upper end electrode 1303, and the fourth upper end electrode 1304) and one lower end electrode (e.g., the lower end electrode 1305 of FIG. 13) of FIG. 13.

For example, referring to FIGS. 17 and 14, the dielectric heating device 300 (e.g., the load circuit 320 of the dielectric heating device 300) may include a plurality of upper end electrodes (e.g., 16 upper end electrodes 1701 to 1716) and a plurality of lower end electrodes (e.g., 16 lower end electrodes 1721 to 1736). The plurality of upper end electrodes (e.g., the 16 upper end electrodes 1701 to 1716) and the plurality of lower end electrodes (e.g., the 16 lower end electrodes 1721 to 1736) may be understood similarly to the plurality of upper end electrodes (e.g., the first upper end electrode 1501, the second upper end electrode 1502, the third upper end electrode 1503, and the fourth upper end electrode 1504) and the plurality of lower end electrodes (e.g., the first lower end electrode 1511, the second lower end electrode 1512, the third lower end electrode 1513, and the fourth lower end electrode 1514) of FIG. 15.

FIG. 18 is a view for describing a structure of a plurality of electrodes of a dielectric heating device according to an embodiment of the disclosure. FIG. 18 may be described with reference to FIGS. 3, 4, 6, and 19. FIG. 19 is a view for describing a load circuit of a dielectric heating device according to an embodiment of the disclosure.

Referring to FIG. 18, according to an embodiment, the dielectric heating device 300 (e.g., the load circuit 320 of the dielectric heating device 300) may include a plurality of electrodes (e.g., the first upper end electrode 1801, the second upper end electrode 1802, the third upper end electrode 1803, the fourth upper end electrode 1804, and the lower end electrode 1805). The plurality of upper end electrodes (e.g., the first upper end electrode 1801, the second upper end electrode 1802, the third upper end electrode 1803, and the fourth upper end electrode 1804) included in the load circuit 320 may be positioned on substantially the same plane. The lower end electrode 1805 included in the load circuit 320 may be disposed on a plane parallel to the plane formed by the plurality of upper end electrodes (e.g., the first upper end electrode 1801, the second upper end electrode 1802, the third upper end electrode 1803, and the fourth upper end electrode 1804).

Referring to FIG. 19, n may be assumed to be 4 to describe the embodiment of FIG. 18. For example, referring to FIG. 19, the dielectric heating device 300 may include a first capacitor C1, a second capacitor C2, a third capacitor C3, and a fourth capacitor C4.

According to an embodiment, the first upper end electrode 1801 and the lower end electrode 1805 may form the first capacitor (e.g., C1 of FIG. 19). A first area (e.g., the area corresponding to the first upper end electrode 1801) of the first upper end electrode 1801 and the lower end electrode 1805 may form the first capacitor (e.g., C1 of FIG. 19). The second upper end electrode 1802 and the lower end electrode 1805 may form the second capacitor (e.g., C2 of FIG. 19). The second area (e.g., the area corresponding to the second upper end electrode 1802) of the second upper end electrode 1802 and the lower end electrode 1805 may form the second capacitor (e.g., C2 of FIG. 19). The third upper end electrode 1803 and the lower end electrode 1805 may form the third capacitor (e.g., C3 of FIG. 19). A third area (e.g., the area corresponding to the third upper end electrode 1803) of the third upper end electrode 1803 and the lower end electrode 1805 may form the third capacitor (e.g., C3 of FIG. 19). The fourth upper end electrode 1804 and the lower end electrode 1805 may form the fourth capacitor (e.g., C4 of FIG. 19). A fourth area (e.g., the area corresponding to the fourth upper end electrode 1804) of the fourth upper end electrode 1804 and the lower end electrode 1805 may form the fourth capacitor (e.g., C4 of FIG. 19). Referring to FIGS. 18 and 19, the first capacitor C1, the second capacitor C2, the third capacitor C3, and the fourth capacitor C4 included in the load circuit 320 may share the lower end electrode 1805. The lower end electrode 1805 included in the load circuit 320 may be electrically connected to an inductor (e.g., L of FIG. 19). The inductor L of FIG. 19 may be a variable inductor.

Referring to FIGS. 18 and 19, the capacitance of the first capacitor C1 formed by the first upper end electrode 1801 and the lower end electrode 1805, the capacitance of the second capacitor C2 formed by the second upper end electrode 1802 and the lower end electrode 1805, the capacitance of the third capacitor C3 formed by the third upper end electrode 1803 and the lower end electrode 1805, and the capacitance of the fourth capacitor C4 formed by the fourth upper end electrode 1804 and the lower end electrode 1805 may be substantially the same. For example, the area of the first upper end electrode 1801, the area of the second upper end electrode 1802, the area of the third upper end electrode 1803, and the area of the fourth upper end electrode 1804 may be substantially the same. For example, the size of the first area of the lower end electrode 1805 corresponding to the first upper end electrode 1801, the size of the second area of the lower end electrode 1805 corresponding to the second upper end electrode 1802, the size of the third area of the lower end electrode 1805 corresponding to the third upper end electrode 1803, and the size of the fourth area of the lower end electrode 1805 corresponding to the fourth upper end electrode 1804 may be substantially the same. According to an embodiment, at least one of the area of the first upper end electrode 1801, the area of the second upper end electrode 1802, the area of the third upper end electrode 1803, and the area of the fourth upper end electrode 1804 may have a different area.

FIG. 18 illustrates that the plurality of electrodes (e.g., the first upper end electrode 1801, the second upper end electrode 1802, the third upper end electrode 1803, the fourth upper end electrode 1804, and the lower end electrode 1805) have a rectangular shape, but this is exemplary, and the shape of the plurality of electrodes (e.g., the first upper end electrode 1801, the second upper end electrode 1802, the third upper end electrode 1803, the fourth upper end electrode 1804, and the lower end electrode 1805) is not limited thereto. For example, the plurality of electrodes (e.g., the first upper end electrode 1801, the second upper end electrode 1802, the third upper end electrode 1803, the fourth upper end electrode 1804, and the lower end electrode 1805) included in the load circuit 320 may have a round shape.

FIG. 18 illustrates that the plurality of upper end electrodes (e.g., the first upper end electrode 1801, the second upper end electrode 1802, the third upper end electrode 1803, and the fourth upper end electrode 1804) are disposed side by side, but this is exemplary, and the plurality of upper end electrodes (e.g., the first upper end electrode 1801, the second upper end electrode 1802, the third upper end electrode 1803, and the fourth upper end electrode 1804) may be disposed in a lattice shape.

Referring to FIGS. 18 and 19, the load circuit 320 including the plurality of electrodes (e.g., the first upper end electrode 1801, the second upper end electrode 1802, the third upper end electrode 1803, the fourth upper end electrode 1804, and the lower end electrode 1805) may be represented as the CLC structure of FIG. 19. The CLC structure of FIG. 19 may be one represented in the circuit diagram in which the first capacitor C1, the second capacitor C2, the third capacitor C3, and the fourth capacitor C4 share the lower end electrode (e.g., the lower end electrode 1805 of FIG. 18). The lower end electrode (e.g., 1805 of FIG. 18) included in the load circuit 320 may be electrically connected to at least one inductor (e.g., L of FIG. 19) included in the load circuit 320. The CLC structure of FIG. 19 represents that the lower end electrode (e.g., the lower end electrode 1805 of FIG. 18) included in the load circuit 320 is electrically connected to at least one inductor L included in the load circuit 320. In the CLC structure of FIG. 19, at least one inductor L included in the load circuit 320 may include a variable inductor.

In the circuit diagram 1910 of FIG. 19, the object (e.g., the target object) disposed between the plurality of electrodes (e.g., the first upper end electrode 1801, the second upper end electrode 1802, the third upper end electrode 1803, the fourth upper end electrode 1804, and the lower end electrode 1805) may be represented as resistors (e.g., r₁, rₙ₋₁, and rₙ).

The dielectric heating device 300 may include one or more power sources 310 and one or more driving circuits 330. The power supply unit including the one or more power sources 310 and the one or more driving circuits 330 may be represented as the plurality of power sources (e.g., V₁, Vₙ₋₁, and Vₙ) of FIG. 19. In the circuit diagram 1910 of FIG. 19, the plurality of power sources (e.g., V₁, Vₙ₋₁, and Vₙ) may be electrically connected to the plurality of capacitors (e.g., C₁, Cₙ₋₁, and Cₙ), respectively.

The dielectric heating device 300 may include a plurality of power sources 310 and a plurality of driving circuits 330 corresponding to the plurality of power sources 310. The dielectric heating device 300 may include one power source 310 and a plurality of driving circuits 330 corresponding to the one power source 310. The plurality of driving circuits 330 may be electrically connected to the plurality of capacitors (e.g., C₁, Cₙ₋₁, and Cₙ of FIG. 19), respectively.

Referring to FIGS. 18 and 19, the dielectric heating device 300 may activate only power sources (e.g., some of the plurality of power sources (e.g., V₁, Vₙ₋₁, and Vₙ)) corresponding to some of the plurality of upper end electrodes (e.g., the first upper end electrode 1801, the second upper end electrode 1802, the third upper end electrode 1803, and the fourth upper end electrode 1804). The dielectric heating device 300 may activate only power sources (e.g., some of the plurality of power sources (e.g., V₁, Vₙ₋₁, and Vₙ)) corresponding to some electrodes among the plurality of upper end electrodes (e.g., the first upper end electrode 1801, the second upper end electrode 1802, the third upper end electrode 1803, and the fourth upper end electrode 1804) based on the type, shape, and/or position of the object (e.g., the target object) disposed between the plurality of electrodes (e.g., the first upper end electrode 1801, the second upper end electrode 1802, the third upper end electrode 1803, the fourth upper end electrode 1804, and the lower end electrode 1805). For example, the dielectric heating device 300 may activate only power sources (e.g., some of the plurality of power sources (e.g., V₁, Vₙ₋₁, and Vₙ)) corresponding to some electrodes corresponding to the position of the target object among the plurality of upper end electrodes (e.g., the first upper end electrode 1801, the second upper end electrode 1802, the third upper end electrode 1803, and the fourth upper end electrode 1804). For example, the dielectric heating device 300 may control on/off of each of the plurality of power sources (e.g., V₁, Vₙ₋₁, and Vₙ). The dielectric heating device 300 may directly control on/off of the plurality of power sources (e.g., V₁, Vₙ₋₁, and Vₙ). When the dielectric heating device 300 includes a plurality of switches corresponding to the plurality of power sources (e.g., V₁, Vₙ₋₁, and Vₙ), the dielectric heating device 300 may control on/off of the plurality of switches corresponding to the plurality of power sources (e.g., V₁, Vₙ₋₁, and Vₙ). The method in which the dielectric heating device 300 controls whether to activate the plurality of power sources (e.g., V₁, Vₙ₋₁, and Vₙ) is not limited.

It may be understood by one of ordinary skill in the art that embodiments described herein may be applied mutually organically within the applicable scope. For example, one of ordinary skill in the art may understand that at least some operations of an embodiment of the disclosure may be omitted and applied and that at least some operations of an embodiment and at least some operations of another embodiment may be organically combined and applied.

According to an embodiment, a dielectric heating device 300 may comprise at least one power source 310, a load circuit 320 including a plurality of electrodes 221, 222, 511, 512, 520, 711, 712, 720, 911, 912, 920, 1301, 1302, 1303, 1304, 1305, 1401, 1402, 1403, 1404, 1406, 1701, 1702, 1703, 1704, 1705, 1706, 1707, 1708, 1709, 1710, 1711, 1712, 1713, 1714, 1715, 1716 and at least one inductor 730 and at least one driving circuit 330 configured to output AC power to the load circuit 320 using power provided from the at least one power source. The plurality of electrodes 221; 222; 511; 512; 520; 711; 712; 720; 911; 912; 920; 1301; 1302; 1303; 1304; 1305; 1401; 1402; 1403; 1404; 1406; 1701; 1702; 1703; 1704; 1705; 1706; 1707; 1708; 1709; 1710; 1711; 1712; 1713; 1714; 1715; 1716 may include a plurality of upper end electrodes 511; 512; 711; 712; 911; 912; 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 positioned on substantially the same plane and one lower end electrode 520; 720; 920; 1305; 1406 disposed on a plane parallel to a plane formed by the plurality of upper end electrodes 511; 512; 711; 712; 911; 912; 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716.

According to an embodiment, the plurality of upper end electrodes 511; 512; 711; 712; 911; 912; 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 may include a first upper end electrode 511; 711; 911 and a second upper end electrode 512; 712; 912. The first upper end electrode 511; 711; 911 and the lower end electrode 520; 720; 920; 1305; 1406 may form a first capacitor. The second upper end electrode 512; 712; 912 and the lower end electrode 520; 720; 920; 1305; 1406 may form a second capacitor.

According to an embodiment, a capacitance of the first capacitor may be substantially the same as a capacitance of the second capacitor.

According to an embodiment, the lower end electrode 520; 720; 920; 1305; 1406 may be electrically connected to the at least one inductor.

According to an embodiment, the at least one inductor 730 may include a variable inductor.

According to an embodiment, the lower end electrode 520; 720; 920; 1305; 1406 may be rotatable.

According to an embodiment, the dielectric heating device 300 may further comprise a plate 940 between a plane formed by the plurality of upper end electrodes 511; 512; 711; 712; 911; 912; 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 and a plane on which the lower end electrode 520; 720; 920; 1305; 1406 is disposed.

According to an embodiment, the plate 940 may be rotatable.

According to an embodiment, the plurality of upper end electrodes 511; 512; 711; 712; 911; 912; 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 may include four or more upper end electrodes 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 having the same area.

According to an embodiment, capacitances formed by each of the four or more upper end electrodes 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716 with the lower end electrode 520; 720; 920; 1305; 1406 may be substantially the same.

According to an embodiment, the at least one driving circuit 330 may include a plurality of driving circuits 330 respectively connected to the four or more upper end electrodes 1301; 1302; 1303; 1304; 1401; 1402; 1403; 1404; 1701; 1702; 1703; 1704; 1705; 1706; 1707; 1708; 1709; 1710; 1711; 1712; 1713; 1714; 1715; 1716.

According to an embodiment, a dielectric heating device 300 may comprise at least one power source 310, a load circuit 320 including a plurality of electrodes 221; 222; 1011; 1012; 1021; 1022; 1211; 1212; 1221; 1222; 1501; 1502; 1503; 1504; 1511; 1512; 1513; 1514; 1601; 1602; 1603; 1604; 1621; 1622; 1623; 1624; 1701; 1702; 1703; 1704; 1705; 1706; 1707; 1708; 1709; 1710; 1711; 1712; 1713; 1714; 1715; 1716; 1721; 1722; 1723; 1724; 1725; 1726; 1727; 1728; 1729; 1730; 1731; 1732; 1733; 1734; 1735; 1736 and at least one inductor 1030, and at least one driving circuit 330 configured to output AC power to the load circuit 320 using power provided from the at least one power source 310. The plurality of electrodes 221; 222; 1011; 1012; 1021; 1022; 1211; 1212; 1221; 1222; 1501; 1502; 1503; 1504; 1511; 1512; 1513; 1514; 1601; 1602; 1603; 1604; 1621; 1622; 1623; 1624; 1721; 1722; 1723; 1724; 1725; 1726; 1727; 1728; 1729; 1730; 1731; 1732; 1733; 1734; 1735; 1736 may include a plurality of upper end electrodes 1011; 1012; 1211; 1212; 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 disposed on a first plane and a plurality of lower end electrodes 1021; 1022; 1221; 1222; 1511; 1512; 1513; 1514; 1621; 1622; 1623; 1624; 1721; 1722; 1723; 1724; 1725; 1726; 1727; 1728; 1729; 1730; 1731; 1732; 1733; 1734; 1735; 1736 disposed on a second plane. The first plane may be parallel to the second plane.

According to an embodiment, the plurality of upper end electrodes 1011; 1012; 1211; 1212; 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 may include a first upper end electrode 1011; 1211 and a second upper end electrode 1012; 1212. The plurality of lower end electrodes 1021; 1022; 1221; 1222; 1511; 1512; 1513; 1514; 1621; 1622; 1623; 1624; 1721; 1722; 1723; 1724; 1725; 1726; 1727; 1728; 1729; 1730; 1731; 1732; 1733; 1734; 1735; 1736 may include a first lower end electrode 1021; 1221 and a second lower end electrode 1022; 1222. The first upper end electrode 1011; 1211 and the first lower end electrode 1021; 1221 may form a first capacitor. The second upper end electrode 1012; 1212 and the second lower end electrode 1022; 1222 may form a second capacitor.

According to an embodiment, a capacitance of the first capacitor may be substantially the same as a capacitance of the second capacitor.

According to an embodiment, the first lower end electrode 1021; 1221 may be electrically connected to the at least one inductor 1030. The second upper end electrode 1012; 1212 may be electrically connected to the at least one inductor 1030.

According to an embodiment, the at least one inductor 1030 may include a variable inductor 1030.

According to an embodiment, the dielectric heating device 300 may further comprise a plate 1230 the first plane and the second plane.

According to an embodiment, the plate 1230 may be rotatable.

According to an embodiment, the plurality of upper end electrodes 1011; 1012; 1211; 1212; 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 may include four or more upper end electrodes 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 having the same area. The plurality of lower end electrodes 1021; 1022; 1221; 1222; 1511; 1512; 1513; 1514; 1621; 1622; 1623; 1624; 1721; 1722; 1723; 1724; 1725; 1726; 1727; 1728; 1729; 1730; 1731; 1732; 1733; 1734; 1735; 1736 may include four or more lower end electrodes 1511; 1512; 1513; 1514; 1621; 1622; 1623; 1624; 1721; 1722; 1723; 1724; 1725; 1726; 1727; 1728; 1729; 1730; 1731; 1732; 1733; 1734; 1735; 1736 having the same area.

According to an embodiment, capacitances formed by each of the four or more upper end electrodes 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 and the four or more lower end electrodes 1511; 1512; 1513; 1514; 1621; 1622; 1623; 1624; 1721; 1722; 1723; 1724; 1725; 1726; 1727; 1728; 1729; 1730; 1731; 1732; 1733; 1734; 1735; 1736 respectively corresponding to the four or more upper end electrodes 1501; 1502; 1503; 1504; 1601; 1602; 1603; 1604; 1701; 1702; 1703; 1704; 1705; 1706; 1707; 1708; 1709; 1710; 1711; 1712; 1713; 1714; 1715; 1716 may be substantially the same.

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

According to embodiments, each component of the above-described components may include a single entity or multiple entities. Some of the plurality of entities may be separately disposed in different components. According to embodiments, one or more of the above-described components may be omitted, or one or more other components may be added. Alternatively or additionally, a plurality of components may be integrated into a single component. In such a case, according to various embodiments, the integrated component may still perform one or more functions of each of the plurality of components in the same or similar manner as they are performed by a corresponding one of the plurality of components before the integration. According to embodiments, operations performed by components may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A dielectric heating device, comprising:
at least one power source;
a load circuit including a plurality of electrodes and at least one inductor; and
at least one driving circuit configured to output alternating current (AC) power to the load circuit using power provided from the at least one power source,
wherein the plurality of electrodes include a plurality of upper end electrodes positioned on substantially the same plane and one lower end electrode disposed on a plane parallel to the plane formed by the plurality of upper end electrodes.

2. The dielectric heating device of claim 1,
wherein the plurality of upper end electrodes include a first upper end electrode and a second upper end electrode,
wherein the first upper end electrode and the lower end electrode form a first capacitor, and
wherein the second upper end electrode and the lower end electrode form a second capacitor.

3. The dielectric heating device of claim 2, wherein a capacitance of the first capacitor is substantially the same as a capacitance of the second capacitor.

4. The dielectric heating device of claim 1, wherein the lower end electrode is electrically connected to the at least one inductor.

5. The dielectric heating device of claim 1, wherein the at least one inductor includes a variable inductor.

6. The dielectric heating device of claim 1, wherein the lower end electrode is rotatable.

7. The dielectric heating device of claim 1, further comprising:
a plate between the plane formed by the plurality of upper end electrodes and the plane on which the lower end electrode is disposed.

8. The dielectric heating device of claim 7, wherein the plate is rotatable.

9. The dielectric heating device of claim 1, wherein the plurality of upper end electrodes include four or more upper end electrodes having the same area.

10. The dielectric heating device of claim 9, wherein capacitances formed by each of the four or more upper end electrodes with the lower end electrode are substantially the same.

11. The dielectric heating device of claim 1, wherein the at least one driving circuit includes a plurality of driving circuits respectively connected to the four or more upper end electrodes.

12. A dielectric heating device, comprising:
at least one power source;
a load circuit including a plurality of electrodes and at least one inductor; and
at least one driving circuit configured to output alternating current (AC) power to the load circuit using power provided from the at least one power source,
wherein the plurality of electrodes include a plurality of upper end electrodes disposed on a first plane and a plurality of lower end electrodes disposed on a second plane, and
wherein the first plane is parallel to the second plane.

13. The dielectric heating device of claim 12,
wherein the plurality of upper end electrodes include a first upper end electrode and a second upper end electrode,
wherein the plurality of lower end electrodes includes a first lower end electrode and a second lower end electrode,
wherein the first upper end electrode and the first lower end electrode form a first capacitor, and
wherein the second upper end electrode and the second lower end electrode form a second capacitor.

14. The dielectric heating device of claim 13, wherein a capacitance of the first capacitor is substantially the same as a capacitance of the second capacitor.

15. The dielectric heating device of claim 12,
wherein the first lower end electrode is electrically connected to the at least one inductor, and
wherein the second upper end electrode is electrically connected to the at least one inductor.

16. The dielectric heating device of claim 12, wherein the at least one inductor includes a variable inductor.

17. The dielectric heating device of claim 12, wherein the lower end electrode is rotatable.

18. The dielectric heating device of claim 12, wherein the plurality of upper end electrodes include four or more upper end electrodes.

19. The dielectric heating device of claim 18, wherein capacitances formed by each of the four or more upper end electrodes with the lower end electrodes are substantially the same.

20. The dielectric heating device of claim 12, wherein the at least one driving circuit includes a plurality of driving circuits respectively connected to the four or more upper end electrodes.
